(19) United States
(12) Patent Application Publication
(10) Pub. No.: US 2025/0290973 A1
(43) Pub. Date: Sep. 18, 2025

(54) SEMICONDUCTOR INTEGRATED CIRCUIT

(71) Applicant: ADVANTEST CORPORATION, Tokyo (JP)

(72) Inventors: Junichi IKEMOTO, Tokyo (JP); Yusuke HAYASE, Tokyo (JP); Yasufumi YODA, Tokyo (JP)

(21) Appl. No.: 19/223,663

(22) Filed: May 30, 2025

Related U.S. Application Data
(63) Continuation of application No. PCT/JP2023/003407, filed on Feb. 2, 2023.

(51) Int. Cl. G01R 31/28

(52) U.S. Cl. CPC G01R 31/2834; G01R 31/2867; G01R 31/2877

(57) ABSTRACT

A pin electronics IC is formed on a semiconductor chip. The pin electronics IC has two dummy areas located on both sides of the semiconductor chip in a first direction, and having no transistor that serves as a heat source arranged therein. A main circuit of the pin electronics IC is formed in an area interposed between the two dummy areas.

### CROSS REFERENCE TO RELATED APPLICATIONS

This application is a continuation under 35 U.S.C. § 120 of PCT/JP2023/003407, filed Feb. 2, 2023, which is incorporated herein by reference, and priority to which is claimed.

### BACKGROUND

### 1. Technical Field

The present disclosure relates to a semiconductor integrated circuit.

### 2. Description of the Related Art

Automatic test equipment (ATE) has been used for inspection of various semiconductor devices including memory and central processing unit (CPU). The ATE is structured to supply a test signal to a semiconductor device to be tested (referred to as device under test (DUT), hereinafter), to measure response of the DUT to the test signal, to determine quality of the DUT, or to identify a defective part.

FIG. 1 is a block diagram of a prior ATE 10. The ATE 10 has a tester (also referred to as a tester body) 20, a test head 30, an interface device 40, and a handler 50.

The tester 20 integrally controls the ATE 10. More specifically, the tester 20 runs a test program, controls the test head 30 and the handler 50, and collects results of measurement.

The test head 30 has hardware structured to generate a test signal to be supplied to each DUT 1, and to detect a signal from the DUT 1 (referred to as a device signal). More specifically, the test head 30 has pin electronics (PE) 32, a power supply circuit (not illustrated), and the like. Each of PE 32 is an application specific IC (ASIC) that contains a driver, a comparator, and the like. Prior PEs 32 were mounted on a printed circuit board called PE board 34 and housed inside the test head 30.

The interface device 40 is also referred to as HIFIX, and relays electrical connection between the test head 30 and each DUT 1. The interface device 40 has a socket board 42. The socket board 42 has a plurality of sockets 44 provided thereon, thus enabling measurement of the plurality of DUTs 1 all at once. An ATE for wafer-level test uses a prove card, in place of the socket board 42.

The plurality of sockets 44 will have loaded thereon the plurality of DUTs 1 with use of the handler 50, where the DUTs 1 are pressed against the sockets 44. Upon completion of the test, the handler 50 unloads the DUTs 1, and sorts non-defective and defective products as necessary.

The interface device 40 has a plurality of cables 46 for connecting the socket board 42 and the test head 30. The test signal generated by the PE 32 is transmitted through the cable 46 to each DUT 1, and the device signal generated by the DUT 1 is transmitted through the cable 46 to the PE 32.

### CITATION LIST

### Patent Literatures

Patent Literature 1: JP 2008-76308 A
Patent Literature 2: WO 2009-034641

Process speed of dynamic random access memory (DRAM) has been accelerated in these years. Graphics double data rate (GDDR) memory, to be mounted on graphic board, has achieved a transmission speed of 21 Gbps in the non-return to zero (NRZ) system under GDDR6X standard.

The next-generation GDDR7 will employ pulse amplitude modulation 4 (PAM4) to accelerate the transmission speed up to 40 Gbps. Also, the NRZ coding has been accelerated year by year, and will be accelerated up to approximately 28 Gbps in the next generation.

As the speed of the DUT increases, the calorific value of the PE 32 increases, thus needing further consideration on cooling.

### SUMMARY

The present disclosure has been arrived at considering such circumstances, where one exemplary embodiment thereof is to provide a semiconductor integrated circuit capable of testing high-speed devices exceeding 20 Gbps.

A semiconductor integrated circuit in some aspect of the present disclosure includes: a semiconductor chip; two dummy areas located on both sides of the semiconductor chip in a first direction, and having no transistor that serves as a heat source arranged therein; and a main circuit of the semiconductor integrated circuit, formed in an area interposed between the two dummy areas.

It is to be noted that any arbitrary combination or rearrangement of the above-described structural components and so forth is effective as and encompassed by the present embodiments. Moreover, all of the features described in this summary are not necessarily required by embodiments so that the embodiment may also be a sub-combination of these described features. In addition, embodiments may have other features not described above.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram of a prior ATE;

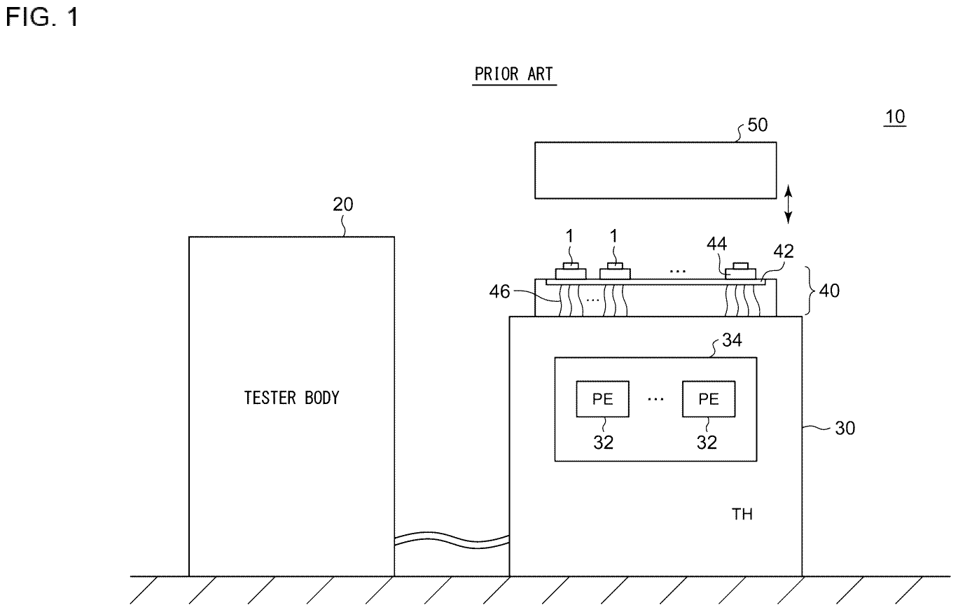

FIG. 2 is a drawing illustrating an ATE according to an embodiment;

FIG. 3 is a cross-sectional view of an interface device according to an Example;

FIG. 4 is a drawing illustrating a front end module according to an Example;

FIG. 5 is a perspective view illustrating an exemplary structure of the FEU illustrated in FIG. 4;

FIG. 6 is a cross-sectional view illustrating an exemplary structure of the FEU illustrated in FIG. 4;

FIG. 7 is a cross-sectional view illustrating an exemplary connection of pin electronics ICs and sockets;

FIG. 8 is a cross-sectional view illustrating an exemplary structure of a connection part between a FPC cable and a socket board;

FIG. 9 is an exploded perspective view illustrating the connection part between the FPC cable and the socket board;

FIGS. 10A and 10B are cross-sectional views for explaining a structure and connection of an interposer;

FIG. 11 is a cross-sectional view illustrating an exemplary structure of a connection part between an FPC cable and a printed circuit board;

FIG. 12 is an exploded perspective view illustrating the connection part between the FPC cable and the printed circuit board;

FIG. 13 is a drawing illustrating a layout of a pin electronics PCB;

FIG. 14 is a simplified layout drawing of the pin electronics PCB;

FIG. 15 is a plan view illustrating a layout of a pin electronics IC;

FIG. 16 is a perspective view illustrating a structure of a dummy area;

FIG. 17 is an exploded perspective view of a cold plate;

FIG. 18 is a perspective view for explaining cooling of a semiconductor chip with use of the cold plate; and

FIG. 19 is a cross-sectional view illustrating a package layout of the pin electronics IC.

### DETAILED DESCRIPTION

### Outline of Embodiments

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

A semiconductor integrated circuit according to one embodiment includes: a semiconductor chip; two dummy areas located on both sides of the semiconductor chip in the first direction, and having no transistor that serves as a heat source arranged therein; and a main circuit of the semiconductor integrated circuit, formed in an area interposed between the two dummy areas.

According to this structure having the main circuit that serves as a heat source interposed between the dummy areas, the heat generated in the main circuit may be dissipated in the horizontal direction and may further be radiated through the dummy areas to the outside.

In one embodiment, the semiconductor chip may have a rectangular shape with the long side aligned in a first direction.

In one embodiment, each of the two dummy areas may have a power supply mesh formed therein. By arranging the power supply mesh in the dummy area, stability of the source voltage can be enhanced.

In one embodiment, the power supply mesh may have a MOS capacitor connected thereto. This can further enhance the stability of the source voltage.

In one embodiment, each of the two dummy areas may have a length in the first direction of 3 mm or longer.

In one embodiment, each dummy area may have a length in the first direction, longer than ⅕ of the length in the first direction of the main circuit.

A module according to one embodiment has any one of the semiconductor integrated circuits described above; and a cold plate having therein a cooling channel, and being thermally coupled to the semiconductor integrated circuit. The cooling channel of the cold plate may be laid in parallel to the first direction.

In one embodiment, the cooling channel of the cold plate may have a U-shaped part that extends towards the first direction and then turns back in an opposite direction.

In one embodiment, the semiconductor chip of the semiconductor integrated circuit may be not encapsulated and may be in contact with the cold plate while placing a heat conductive material in between.

In one embodiment, the semiconductor integrated circuit may be an FC-PGA package and may be mounted on a printed circuit board while placing an interposer in between.

### Embodiments

Preferred embodiments will be explained below, referring to the attached drawings. All similar or equivalent constituents, members and processes illustrated in the individual drawings will be given same reference signs, so as to properly avoid redundant explanations. The embodiments are merely illustrative and are not restrictive about the invention. All features and combinations thereof described in the embodiments are not always necessarily essential to the disclosure and invention.

Dimensions (thickness, length, width, etc.) of the individual members illustrated in the drawings may be appropriately enlarged or shrunk for easy understanding. Furthermore, the dimensions of the plurality of members do not necessarily indicate the dimensional relationship among them, so that a certain member A, if depicted thicker than another member B in a drawing, may even be thinner than the member B.

In the present specification, a “state in which a member A is coupled to a member B” includes a case where the member A and the member B are physically and directly coupled, and a case where the member A and the member B are indirectly coupled while placing in between some other member that does not substantially affect the electrically coupled state, or does not degrade the function or effect demonstrated by the coupling thereof.

Similarly, a “state in which a member C is provided between the member A and the member B” includes a case where the member A and the member C, or the member B and the member C are directly coupled, and a case where they are indirectly coupled, while placing in between some other member that does not substantially affect the electrically coupled state among the members, or does not degrade the function or effect demonstrated by the members.

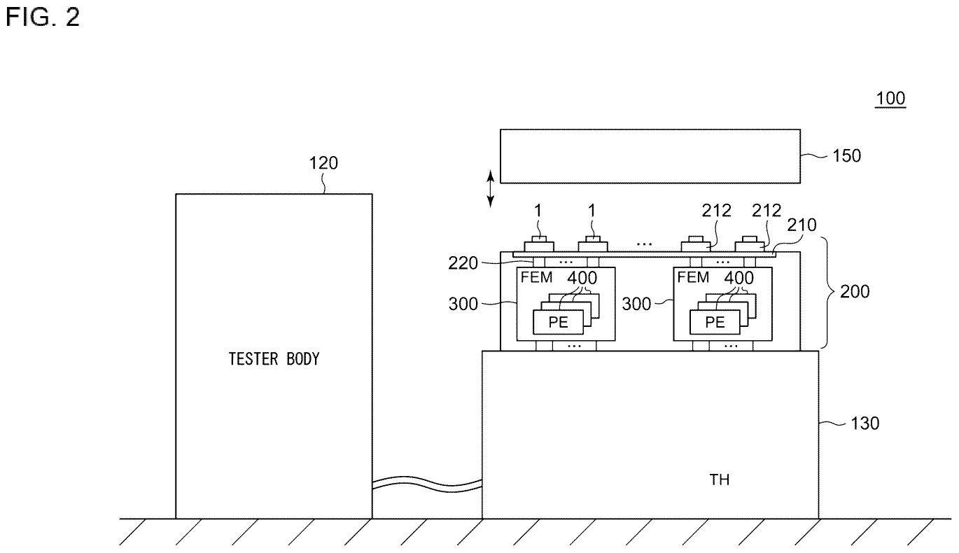

FIG. 2 is a drawing illustrating an ATE 100 according to one embodiment. The ATE 100 has a tester 120, a test head 130, a handler 150, and an interface device 200.

The tester 120 integrally controls the ATE 100. More specifically, the tester 120 runs a test program product, controls the test head 130 and the handler 150, and collects results of measurement.

The handler 150 feeds (loads) the DUTs 1 to the interface device 200, and unloads the tested DUTs 1 from the interface device 200. The handler 150 sorts the DUTs 1 into non-defective ones and defective ones.

The interface device 200 has a socket board 210, wirings 220, and front end modules 300.

In this embodiment, a plurality of pin electronics ICs (PE-ICs) 400 are provided in the interface device 200, not in the test head 130. Each pin electronics IC 400 is an application specific integrated circuit (ASIC), in which a driver that generates a test signal, and a comparator that receives a device signal are integrated. The test signal and the device signal are NRZ signal or PAM4 signal.

More specifically, the plurality of pin electronics ICs 400 are modularized. This module is referred to as a front end module 300.

The socket board 210 has a plurality of sockets 212 provided thereto. Each socket 212 will have a DUT 1 mounted thereon. Each front end module 300 and each socket 212 are connected through the wiring 220.

The structure of the ATE 100 has been described.

The ATE 100 has the interface device 200 that incorporates the front end modules 300 each having the plurality of pin electronics ICs 400 modularized therein, thus making it possible to arrange the pin electronics ICs 400 very close to the DUTs 1. This greatly shortens the transmission distance of the test signal and the device signal, as compared with the prior equipment.

For example, the prior ATE has connected the pin electronics IC and the socket board with a coaxial cable having a length of approximately 500 mm to 600 mm. In contrast, this embodiment can shorten the length of the wiring 220 down to approximately 100 mm to 150 mm. This can greatly reduce loss of high-frequency component and enables high speed transmission of the test signal and the device signal. The ATE 100 thus equipped with the interface device 200 is allowed for test of high-speed memory exceeding 20 Gbps.

The present disclosure may be understood from the block diagram illustrated in FIG. 2 or other circuit diagram, and encompasses various apparatuses and methods derived from the foregoing explanations, without being limited to any specific structure. Hereinafter, more specific exemplary structures and examples will be described to help understanding or to clarify the spirit of the disclosure or the operations, without narrowing the scope of the present disclosure.

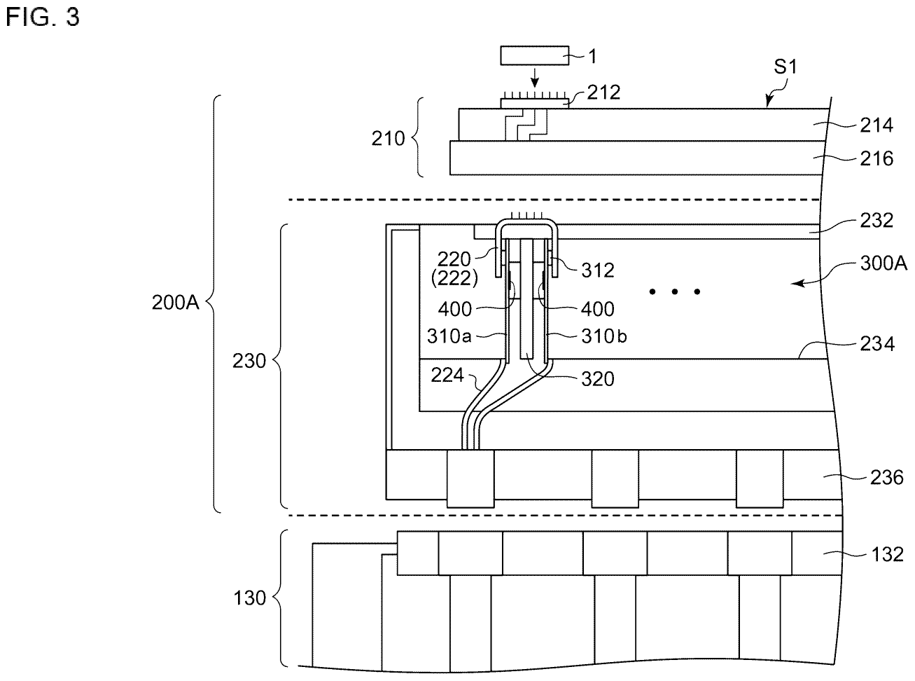

FIG. 3 is a cross-sectional view of an interface device 200A according to one Example. FIG. 3 illustrates only a structure relevant to one DUT. In this Example, the interface device 200A has a motherboard 230, and a socket board 210 detachable from the motherboard 230. The socket board 210 has a socket 212, a socket printed circuit board (socket PCB) 214, and an on-socket-board connector 216.

The front end module 300A has a plurality of printed circuit boards (pin electronics PCBs) 310 on which a plurality of pin electronics ICs 400 are mounted. The plurality of pin electronics PCBs 310 are arranged vertically to faces (top face and back face) of the DUT, in other words a face S1 of the socket board 210. In this Example, the socket board 210 is arranged horizontally to the ground, so that the plurality of pin electronics PCBs 310 are arranged in parallel to the direction of gravity.

The front end module 300A further has a plate-like cooling device (referred to as cold plate, hereinafter) 320. The cold plate 320 has a flow channel through which a refrigerant flows.

The plurality of pin electronics PCBs 310a, 310b and the cold plate 320 are stacked, so as to thermally couple the pin electronics ICs 400 with the cold plate 320.

The motherboard 230 has an on-socket-board connector 232, a spacing frame 234, and a relay connector 236. The front end module 300A is fixed to the spacing frame 234. The relay connector 236 is electrically and mechanically coupled to an on-test-head connector 132.

As will be detailed later, the wiring 220 may employ a cable constituted by a flexible printed circuit (FPC) (also referred to as FPC cable), in place of the prior coaxial cable.

On the other hand, a wiring 224 between the pin electronics PCBs 310 and the relay connector 236 allows only a control signal for the pin electronics IC 400 transmitted therethrough, and through which the test signal and the device signal do not transmit. The wiring 224 may therefore employ a coaxial cable.

The plurality of pin electronics ICs 400 are mounted on the pin electronics PCBs 310, closer to the DUT (closer to the socket board 210) than the center of the pin electronics PCBs 310 in the vertical direction. This successfully shortens the transmission distance of the test signal and the device signal on the pin electronics PCBs 310, thus enabling high-speed signal transmission.

For example, each of the plurality of pin electronics ICs 400 is preferably arranged within 50 mm from one side, closer to the DUT, of the pin electronics PCBs 310. Arrangement within 30 mm, if possible, will be able to further shorten the transmission distance.

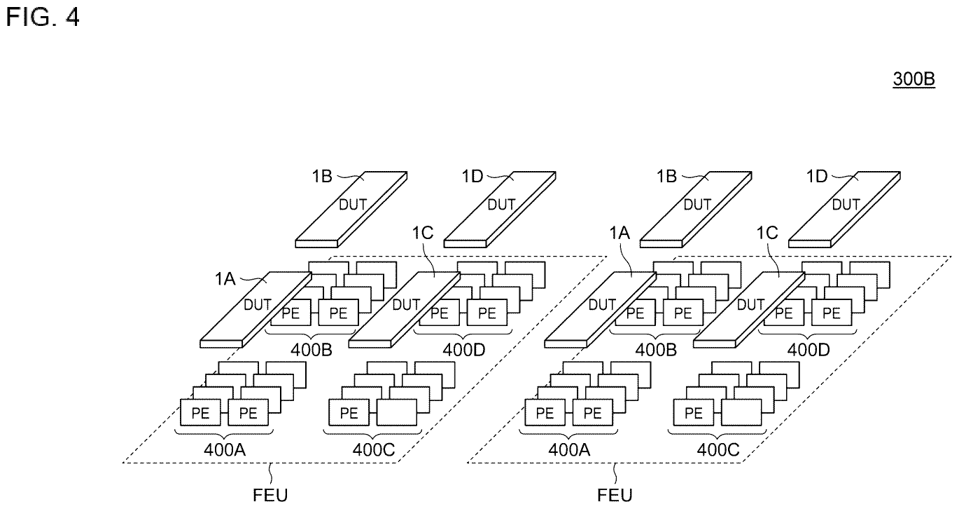

FIG. 4 is a drawing illustrating a front end module 300B according to one Example.

To one DUT 1, assigned are 2×M (M≥1) pin electronics ICs 400. The plurality of DUTs and the pin electronics ICs 400 will be distinguished as necessary, with use of subscripts A to D. In this Example, assuming that each DUT 1 has 192 I/Os and each pin electronics IC 400 has 24 I/Os, then eight (=192/24, and then M=4) pin electronics ICs 400 are assigned per DUT.

The front end module 300B is divisionally structured for every N (N≥2) DUTs 1, where such divisional unit is referred to as front end unit (FEU). In this Example, a block that corresponds to four DUTs constitutes one FEU, and each FEU contains 2×M×N=2×4×4=32 pin electronics ICs 400.

Although only two FEUs are illustrated in FIG. 4, an actual front end module 300B may have two or more FEUs. For an exemplary ATE allowed for parallel measurement for 64 FEUs, there are 64/4=16 FEUs provided thereto, and this means provision of 64×192 I/Os=12288 I/Os for the front end module 300B as a whole.

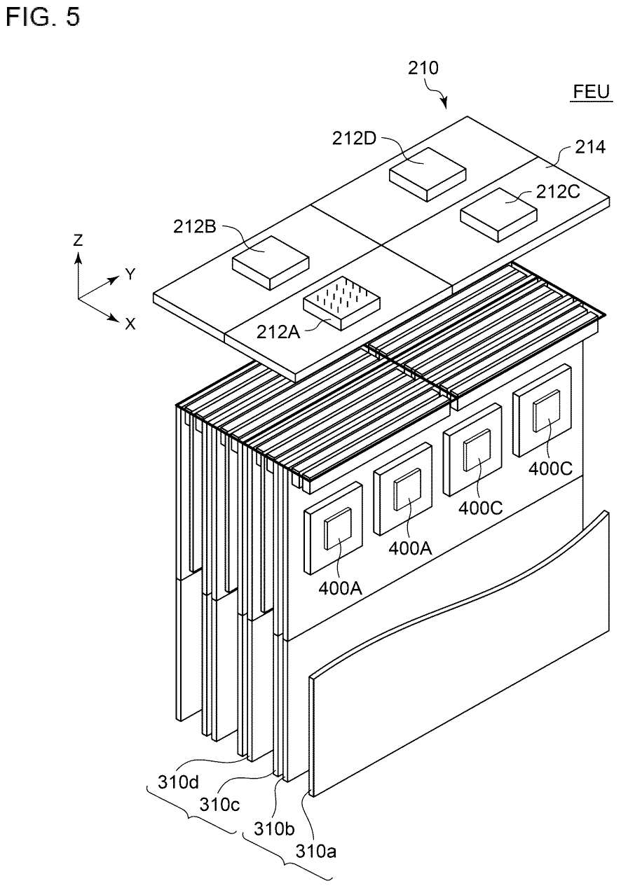

FIG. 5 is a perspective view illustrating an exemplary structure of the FEU illustrated in FIG. 4. Sockets 212A to 212D that correspond to the four DUTs are arranged in a 2-by-2 matrix. Now placing a focus on one DUT 1A, the eight pin electronics ICs 400A assigned thereto are mounted by twos on four pin electronics PCBs 310a to 310d arranged in the X-direction. The socket PCB 214 having the sockets 212 mounted thereon may be divided for each DUT, or the socket PCBs 214 that correspond to four DUTs may be integrated as a single board.

The two pin electronics ICs 400A mounted on one pin electronics PCB 310 are arranged side by side in the Y-direction. The two pin electronics ICs 400A are arranged at positions equidistant from the DUT 1A.

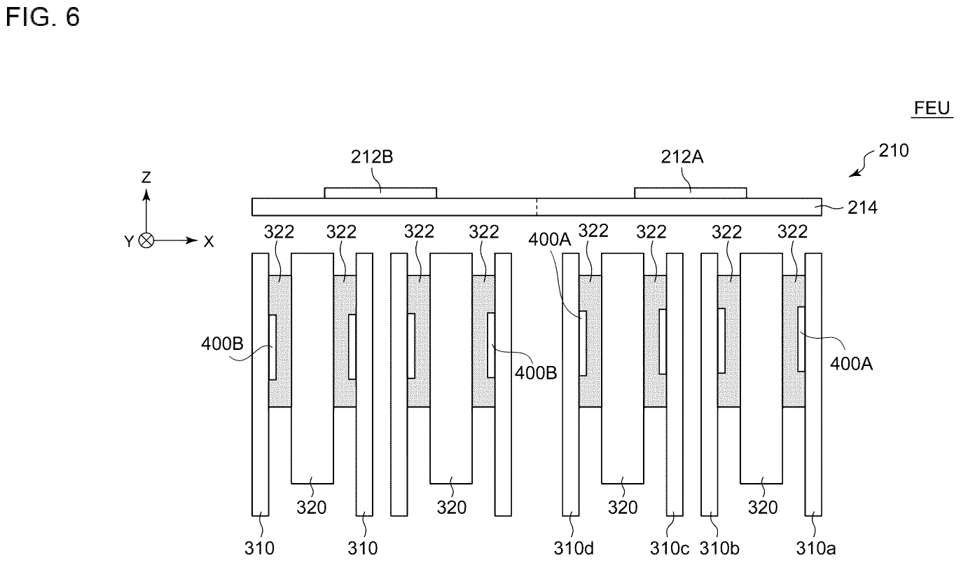

FIG. 6 is a cross-sectional view illustrating an exemplary structure of the FEU illustrated in FIG. 4. As has been also illustrated in FIG. 3, there is the cold plate 320 arranged between the two pin electronics PCBs 310a and 310b. Similarly, the cold plate 320 is also arranged between two pin electronics PCBs 310c and 310d. As has been described above, each pin electronics IC 400 is mounted on the pin electronics PCB 310 close to the socket board 210. The pin electronics ICs 400 may have a bare chip design for improved cooling efficiency. The pin electronics ICs 400 and the cold plate 320 are thermally coupled through a thermal interface material (TIM) 322.

When viewing the FEU in a plan view along the Y-axis, the center of the DUT, or the socket 212A, is positioned at the center of the four (M) pin electronics PCBs 310a to 310d stacked in the X-direction.

The structure of the FEU has been described.

An advantages of the FEU will be explained. A focus is now place on the DUT 1A having a subscript A. With a plurality of (eight in this example) pin electronics ICs 400A that correspond to one DUT 1A, mounted by twos on each of the four pin electronics PCBs 310a to 310d, it now becomes possible to equalize the distance from each of the eight pin electronics ICs 400A to the socket 212A. This successfully equalizes the loss on transmission lines from the individual pin electronics ICs 400A to the socket 212A (DUT 1A), thus enabling accurate test.

Next, electrical connection between the pin electronics IC 400 and the socket 212 will be described.

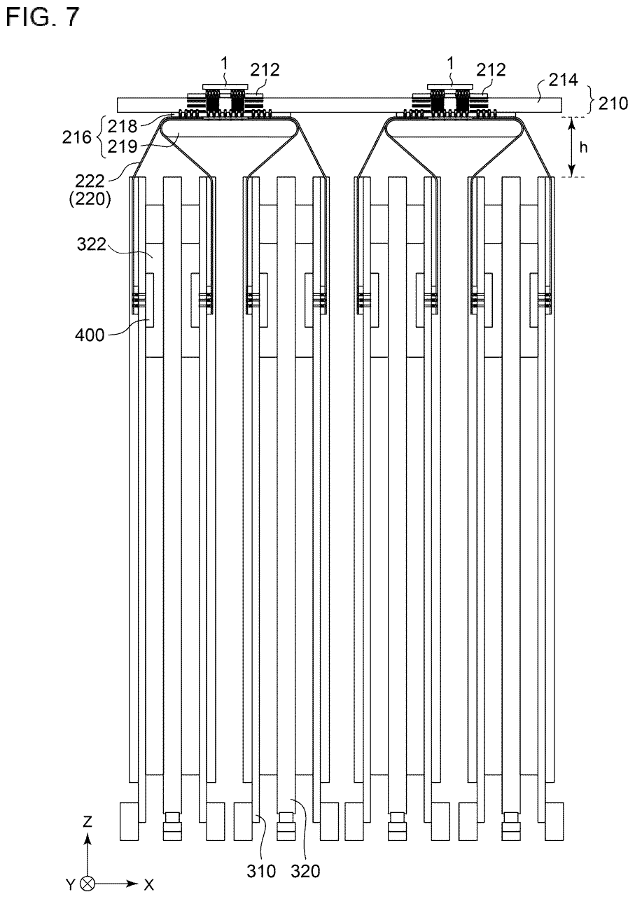

FIG. 7 is a cross-sectional view illustrating an exemplary connection of the pin electronics ICs and the sockets (DUT 1). An FPC cable 222 is used for a transmission path through which the test signal and the device signal are transmitted, that is, the wiring 220 between each pin electronics PCB 310 and the socket board 210.

Use of a coaxial cable for the wiring 220 between each pin electronics PCB 310 and the socket board 210 would limit the shortest distance between the pin electronics PCB 310 and the socket board 210, due to rigidity of the coaxial cable. In contrast, use of the FPC cable 222 can shorten distance h between each pin electronics PCB 310 and the socket board 210 owing to its flexibility, as compared with the case of using the coaxial cable and can shorten the transmission distance of the test signal and the device signal.

A prior test equipment has usually used a low insertion force (LIF) connector, when the socket board 210 is desired to be detachable. The LIF connector has a non-negligible loss of as much as approximately-3 dB in a frequency band higher than 14 GHz. This causes waveform distortion in high-speed transmission at 28 Gbps or 40 Gbps. Use of the FPC cable 222 for the wiring 220 will no longer need the LIF connector and can therefore suppress the waveform distortion due to the loss (attenuation in a high-frequency band), thus enabling accurate test.

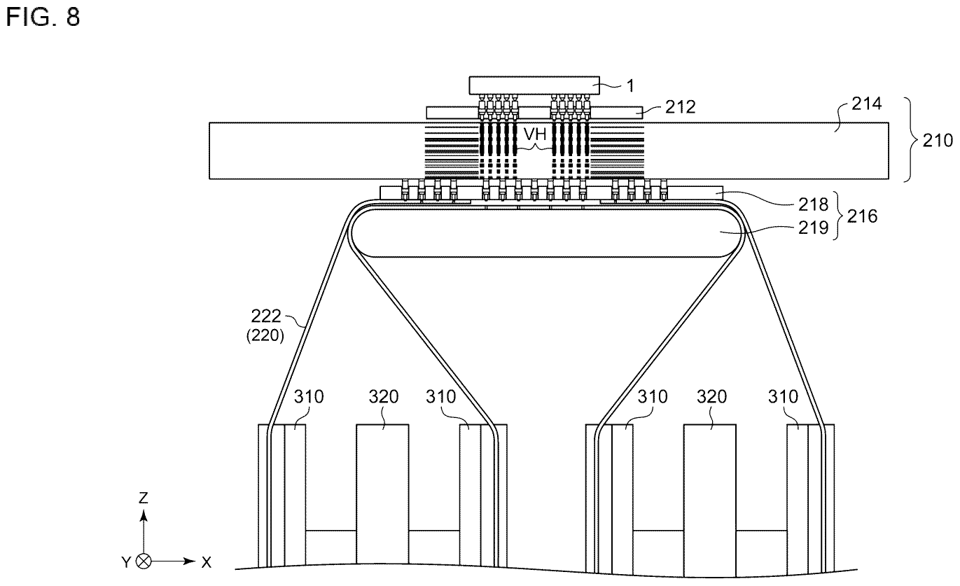

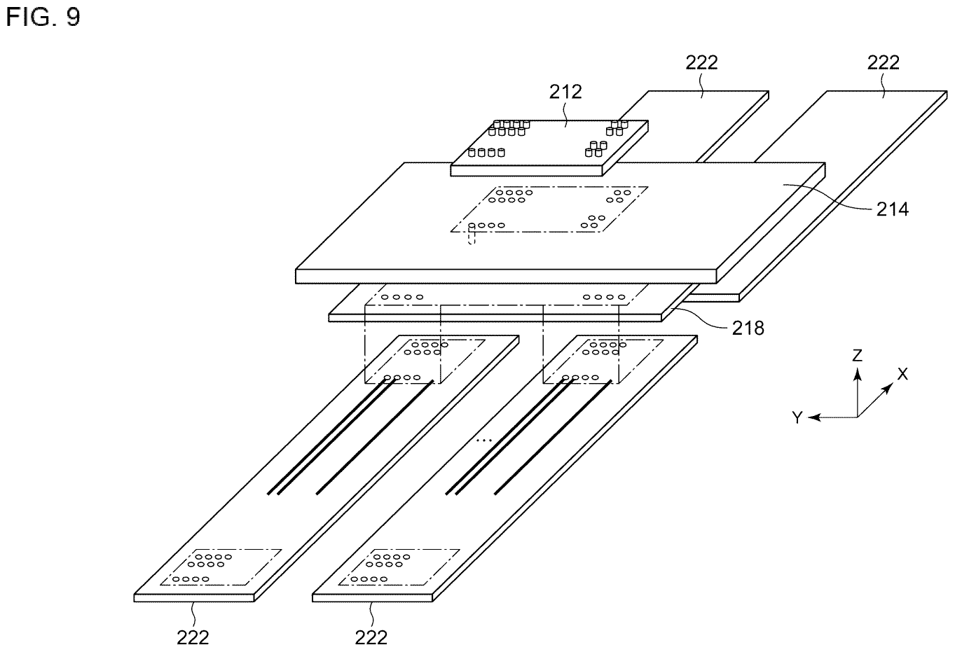

FIG. 8 is a cross-sectional view illustrating an exemplary structure of a connection part between the FPC cable 222 and the socket board 210. FIG. 9 is an exploded perspective view illustrating the connection part between the FPC cable 222 and the socket board 210.

The socket board 210 has the socket 212 and the socket PCB 214. The socket PCB 214 is a multilayer board having interconnect layers and insulating layers. Each interconnect layer has formed therein an interconnect in which a signal path is routed in the horizontal direction, and each insulating layer has formed therein a via hole VH through which the signal path is routed in the vertical direction. The path through which the test signal and the device signal are transmitted is preferably drawn out to the back face of the socket board 210, without being routed as possible in the horizontal direction.

The FPC cable 222 and the socket board 210 are connected through the on-socket-board connector 216. The on-socket-board connector 216 has an interposer 218 and a cable clamp 219.

Electrodes that expose to the top face of the interposer 218 are electrically connected to electrodes that expose to the back face of the socket PCB 214. The FPC cable 222 is clamped by the cable clamp 219, while being kept contact with back electrodes of the interposer 218.

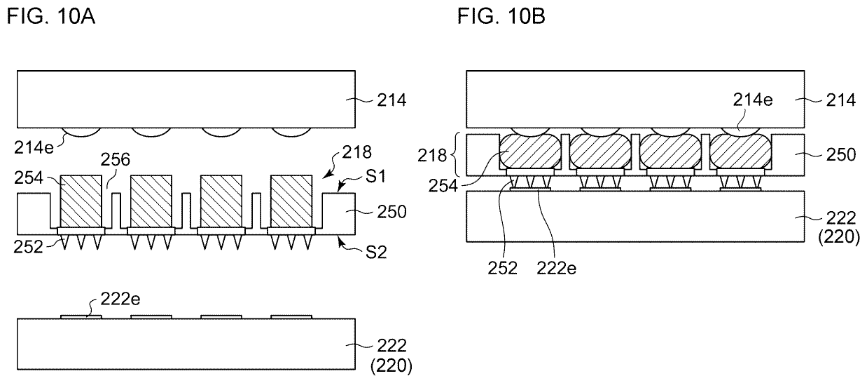

FIGS. 10A and 10B are cross-sectional views for explaining a structure and connection of the interposer. FIG. 10A illustrates a state before connection, and FIG. 10B illustrates a state after connection. The interposer 218 has a board 250, non-deformable electrodes 252, and deformable electrodes 254. The board 250 has on a first face S1 thereof, openings 256 in which the deformable electrodes 254 are embedded. The deformable electrodes 254 are electro-conductive and elastic and protrude out from one face of the board 250 before connection. The deformable electrodes 254 may be formed of an electro-conductive gasket or a conductive elastomer. Alternatively, the deformable electrode 254 may be an electrode with a spring, such as pogo pin.

The board 250 has non-deformable electrodes 252 provided on a second face S2 thereof. The non-deformable electrodes 252 are electrically connected to the deformable electrodes 254 inside the board 250. The non-deformable electrodes 252 are formed of a plurality of protrusions, thus enabling multi-point connection.

Upon pressurizing the socket PCB 214 and the FPC cable 222 while placing the interposer 218 in between as illustrated in FIG. 10B, the non-deformable electrodes 252 of the interposer 218 come into contact with electrodes 222e of the FPC cable 222. Meanwhile, the deformable electrodes 254 deform while being in contact with the back electrodes 214e of the socket PCB 214.

This sort of interposer 218, which can be structured to have smaller parasitic capacitance as compared with the LIF connector or ZIF connector, will excel in high frequency characteristic, and can therefore achieve a flat transmission characteristic (S21 coefficient in the S parameters) over the range from 0 to 40 GHz.

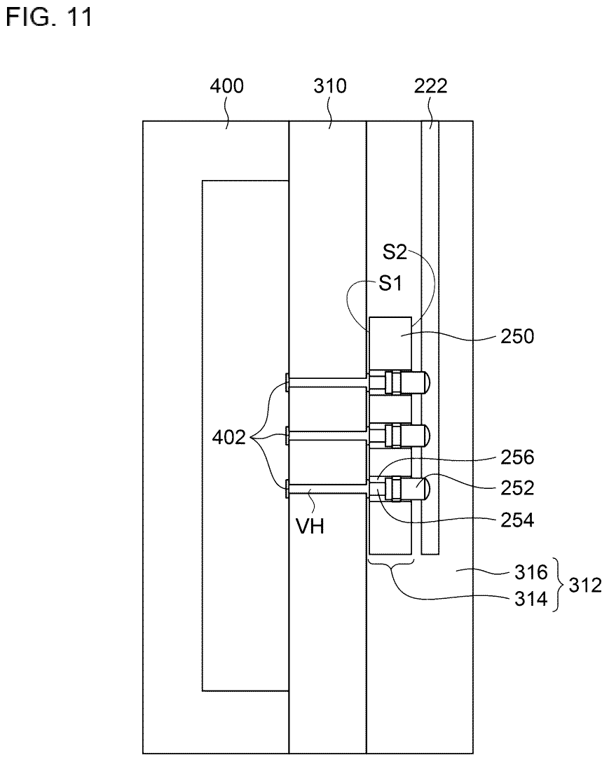

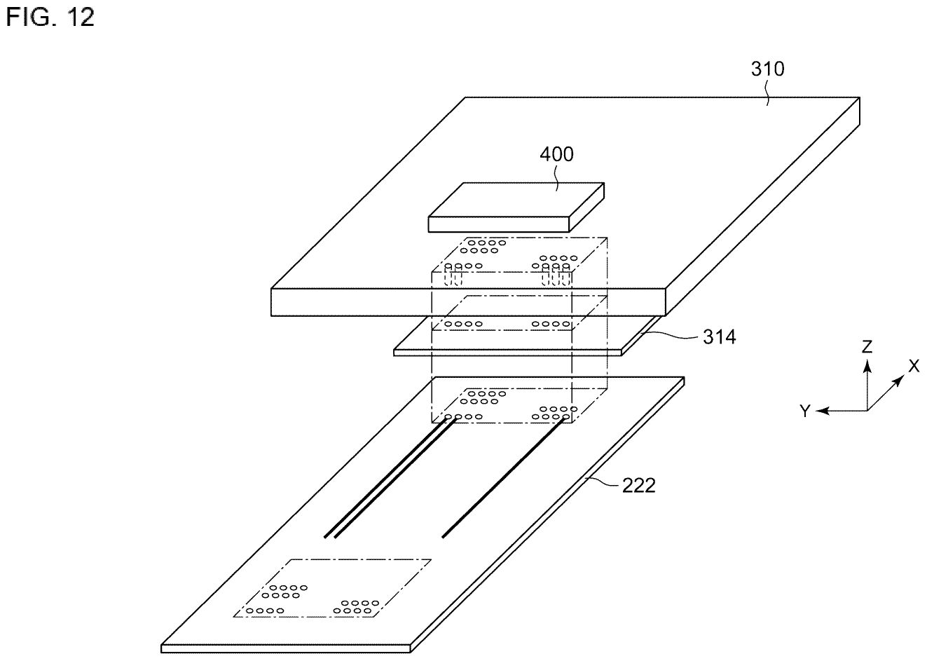

FIG. 11 is a cross-sectional view illustrating an exemplary structure of a connection part between the FPC cable 222 and the pin electronics PCB 310. FIG. 12 is an exploded perspective view illustrating the connection part between the FPC cable 222 and the pin electronics PCB 310.

Reference will be made on FIG. 11. The FPC cable 222 and the pin electronics PCB 310 are connected through the FPC connector 312. The FPC connector 312 is structured similarly to the on-socket-board connector 216 and specifically has an interposer 314 and a cable clamp 316.

The deformable electrodes 254 that expose to the first face S1 of the interposer 314 are electrically connected to electrodes on the back face of the pin electronics PCB 310. The FPC cable 222 is clamped by the cable clamp 316, while being kept in contact with the non-deformable electrodes 252 that expose to the second face S2 of the interposer 314.

The pin electronics PCB 310 has viaholes VH formed therein. The transmission path of the test signal and the device signal is preferably most shortened, also inside the pin electronics PCB 310. The viaholes VH formed in the pin electronics PCB 310 are therefore preferably arranged at positions that overlap the back electrodes 402 of the pin electronics IC 400. This successfully avoids routing of the transmission path inside the pin electronics PCB 310 in the in-plane direction of the printed circuit board, thus enabling high-speed signal transmission.

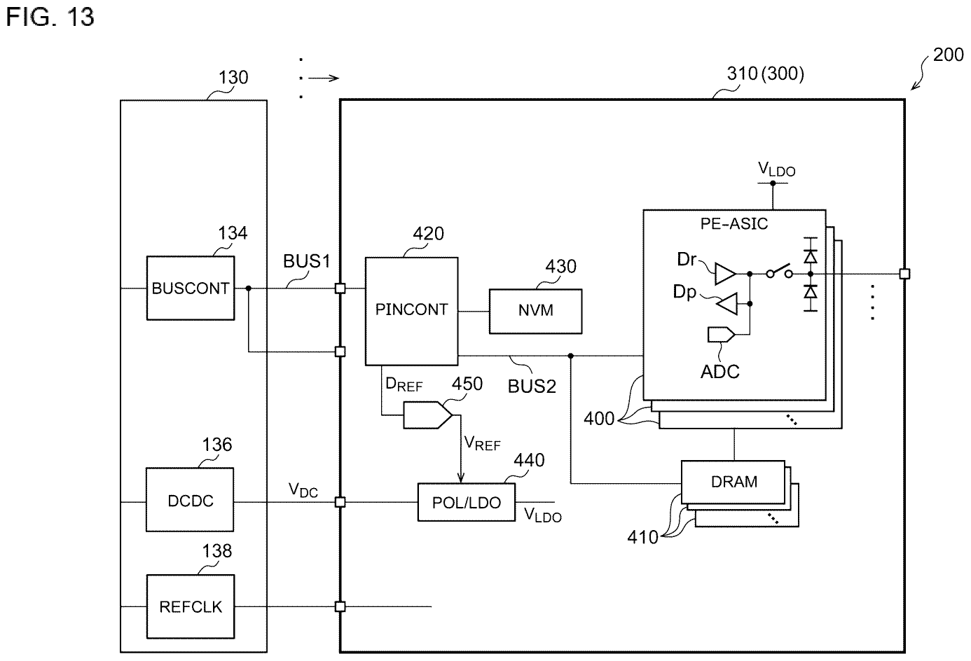

FIG. 13 is a drawing illustrating a layout of a pin electronics PCB 310. On the pin electronics PCB 310, there are the plurality of pin electronics ICs 400, RAMs 410, a pin controller 420, a non-volatile memory 430, and a linear regulator 440 mounted thereon.

The test head 130 has a bus controller 134, a DC/DC converter 136, and an oscillator 138.

The pin controller 420 is connected through an external bus BUS1 to the bus controller 134. The pin controller 420 integrally controls the pin electronics PCB 310 (that is, the front end module 300), in response to the control signal from the bus controller 134. The pin controller 420 may be constituted by a field programmable gate array (FPGA) or a CPU.

The pin controller 420 and the pin electronics IC 400 are connected through a local bus BUS2, through which the control signal, data, and various error signals can be transmitted or received. The pin controller 420 controls the pin electronics ICs 400, and causes the pin electronics ICs 400 to generate the test signal for the DUT 1. Each pin electronics IC 400 has a driver Dr, a comparator Cp, an A/D converter ADC and the like, for each I/O pin. Each I/O pin has a diode for ESD protection connected thereto.

Each pin electronics IC 400 receives the device signal from the unillustrated DUT 1. Each pin electronics IC 400 stores data ascribed to the received device signal, in the RAMs 410. Each RAM 410 is typically a random access memory (DRAM).

The non-volatile memory 430 typically stores configuration data of the pin controller 420, and data that defines operation conditions of the pin controller 420 and the entire front end module 300.

The pin controller 420 reads data from the RAMs 410 and transmits the data to the bus controller 134.

The linear regulator 440 is a power supply circuit called low drop output (LDO) regulator. The linear regulator 440 has an input node, to which DC voltage V_{DC} is supplied from the DC/DC converter 136 provided to the test head 130 and thus generates source voltage V_{LDO}. The source voltage V_{LDO} is supplied to the pin electronics ICs 400, and is used as power source typically for the driver Dr and the comparator Cp.

A D/A converter 450 receives voltage setting data DREF from the pin controller 420 and converts the received data into an analog reference voltage VREF. The source voltage V_{LDO} generated by the linear regulator 440 has a voltage level given by constant multiple of the reference voltage VREF.

A digital circuit in the pin electronics PCB 310, typically including the pin controller 420, a part of the pin electronics ICs 400, the non-volatile memory 430, and the RAMs 410, operates in synchronization with a clock signal CLK supplied from the oscillator 138 of the test head 130.

The structure of the front end module 300 has been described.

This structure has the RAMs 410 mounted on the pin electronics PCB 310 on which the plurality of pin electronics ICs 400 are mounted, whereby a large volume of device signals can be temporarily stored in the RAMs 410 and then transmitted by the pin controller 420 to the test head 130. The transmission rate of the external bus BUS1 that connects the test head 130 and the pin electronics PCB 310 can therefore be designed significantly lower than the rate of the DUT 1.

The present inventors have recognized that, in testing of high-speed devices, the noise contained in the source voltage V_{LDO} of the pin electronics ICs 400 would greatly affect the performance of the pin electronics ICs 400. On the basis of this recognition, the present inventors decided to mount the linear regulator 440 on the pin electronics PCB 310 illustrated in FIG. 13, rather than on the test head 130. The linear regulator 440, if mounted on the test head 130, would make a power source line longer, and this possibly contaminates the source voltage V_{LDO} supplied to the pin electronics ICs 400 with noise, thereby degrading the performance of the pin electronics ICs 400. In contrast, mounting of the linear regulator 440 on the pin electronics PCB 310 can shorten the power source line from the linear regulator 440 to the pin electronics IC 400, thus allowing the source voltage V_{LDO} to flow only through the interconnect routed on the pin electronics PCB 310. This successfully suppresses the pin electronics ICs 400 from being contaminated with noise.

Another feature of the structure illustrated in FIG. 13 is that the DC/DC converter 136, which is a possible noise source, is provided in the test head 130, and thus separated from the linear regulator 440. This successfully suppresses the noise generated by the DC/DC converter 136 from entering the pin electronics ICs 400.

The oscillator 138 that generates the clock signal CLK is provided on the test head 130, rather than on the pin electronics PCB 310. This successfully keeps the oscillator 138, which is a noise source, apart from analog blocks such as the pin electronics ICs 400 and the linear regulator 440 and can suppress the performance of the circuits from degrading.

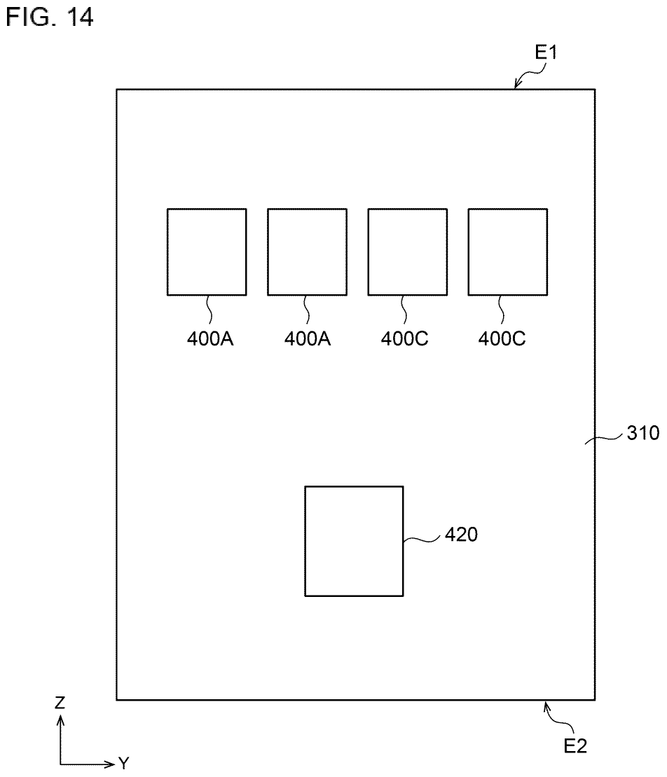

FIG. 14 is a simplified layout drawing of the pin electronics PCB 310. The plurality of pin electronics ICs 400 are mounted on the pin electronics PCB 310 along a first side E1 thereof, which is closest to the DUT 1. This successfully keeps the plurality of pin electronics ICs 400 close to the DUT, thus shortening the transmission distance of the test signal and the device signal.

Assuming now a direction the first side E1 lies as the first direction (Y-direction), and the direction perpendicular thereto as a second direction (Z-direction), then the pin controller 420 is arranged at the center of the pin electronics PCB 310 in the first direction (Y-direction), and closer to a second side E2 opposed to the first side E1 than the center of the pin electronics PCB 310 in the second direction (Z-direction). This layout, having the pin electronics ICs 400 arranged apart from the test head 130, which serves as a heat source and a noise source, and having the pin controller 420 arranged closer to the test head 130, can suppress characteristics of the front end module 300 from degrading.

There are various types of interface device 200, to any of which the present disclosure is applicable.

### Socket Board Change (SBC) Type

SBC type is a type of interface device structured to exchange the socket board 210 depending on types of the DUT.

### Cable-Less (CLS) Type

CLS type is a type of interface device structured so that the interface device 200 is separable into an upper device specific adapter (DSA) and a lower motherboard, wherein the DSA is exchangeable depending on types of the DUT. The interface device 200 of this embodiment, if designed as the CLS type system, may be applicable in two ways.

One of them is to arrange the front end module 300 on the mother board. The front end module 300 in this case may be shared by different tests for the DUTs and has a cost advantage.

The other one is to arrange the front end module 300 on the DSA. The front end module 300 in this case is provided for each DSA and thus pushes up the equipment cost. On the other hand, the front end module 300 in this case may be located close to the DUT and is advantageous from the viewpoint of high-speed testing.

### Cable Connection (CCN) Type

CCN type is a type of interface device structured to exchange the interface device 200 as a whole, depending on types of the DUT. The interface device 200 of this embodiment, if applied to the CCN type, can bring the front end module 300 as close as possible to the DUT, which is advantageous from the viewpoint of high-speed testing.

### Wafer Motherboard

The interface device 200 may alternatively be a wafer motherboard used for wafer level testing. The interface device 200 in this case may have a probe card, instead of the socket board.

Next, a layout of the pin electronics IC 400 will be described. As the speed of the DUT increases, the pin electronics IC 400 will greatly increase heat generation, thus needing some countermeasure.

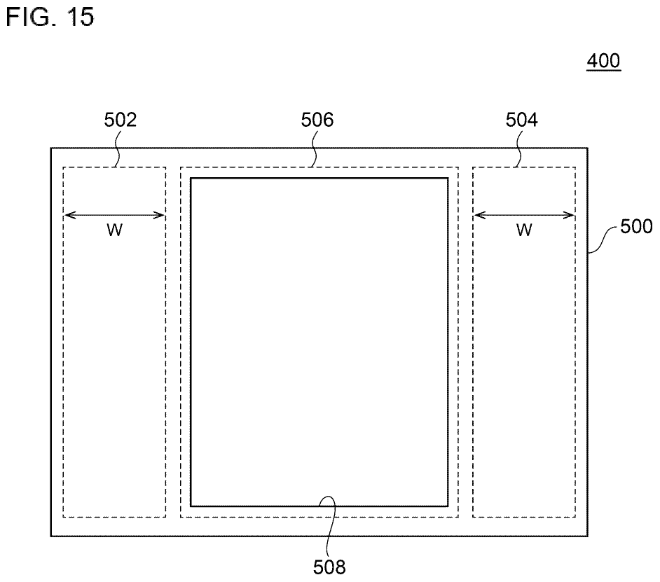

FIG. 15 is a plan view illustrating a layout of the pin electronics IC 400. The pin electronics IC 400 is integrated on a semiconductor chip (die) 500. The pin electronics IC 400 has two dummy areas 502, 504 located at both ends in the first direction (transverse direction on this sheet). The dummy areas 502, 504 have no active element that possibly generates heat arranged therein. The active element that possibly generates heat may include always-on transistor or switchable transistor. Conversely, the dummy areas 502, 504 may have arranged therein any active element that will not generate heat, or whose power consumption is substantially zero. For example, a MOS capacitance or the like may be arranged.

In an area (also referred to as functional area, hereinafter) 506 interposed between the dummy areas 502, 504, there is formed a main circuit 508 on which the function of the pin electronics IC 400 is implemented.

The structure of the pin electronics IC 400 has been described. Next, operations thereof will be described.

The pin electronics IC 400 generates heat in the functional area 506, as a result of operation of the main circuit 508. The heat diffuses into the two dummy areas 502, 504 each adjoining to the functional area in the first direction (left-right direction of this sheet). That is, each of the dummy areas 502, 504 functions as a silicon heat spreader. This successfully suppresses temperature rise of the main circuit 508.

In this embodiment, the semiconductor chip 500 has a rectangular shape with the long side aligned in the first direction. This successfully makes the width W of the dummy areas 502, 504 larger.

Make sure that the dummy areas 502, 504 are not I/O areas. The I/O areas are used for arranging protective elements against surge or electrostatic discharge (ESD) around I/O bonding pads, whose width is several hundred micrometers at most. In contrast, each of the dummy areas 502, 504 in this embodiment has a width W of at least 1 mm, preferably 3 mm or wider, proving that the size and function are completely different.

The length W of each of the two dummy areas 502, 504 in the first direction may be longer than ⅕ of the length L in the first direction of the functional area 506 in which the main circuit 508 is formed.

The pin electronics IC 400 is preferably housed in an FC-PGA package, thus making the semiconductor chip 500 free of bonding pads arranged in the outer periphery.

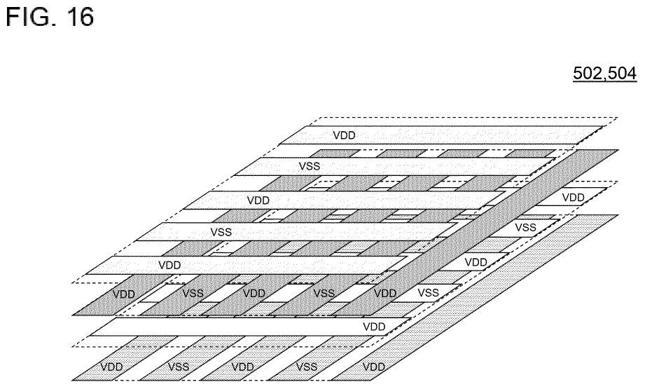

FIG. 16 is a perspective view illustrating a structure of the dummy areas 502, 504. The two dummy areas 502, 504 preferably have a power supply mesh formed therein. The power supply mesh has formed therein a plurality of power supply interconnects in a power supply (VDD) rail, and a plurality of ground interconnects in a ground (VSS) rail, arranged over a plurality of layers to form a lattice structure. The power supply interconnects in different layers are connected through viaholes, and also the ground interconnects in different layers are connected through the viaholes, although not illustrated in FIG. 16.

In each interconnect layer, the power supply interconnects VDD and the ground interconnects VSS are alternately formed in the same direction. In the adjacent interconnect layers, the interconnects are laid in directions orthogonal to each other.

Although it is difficult for the usual LSI to form the power supply mesh in a wide area and in multiple layers, this embodiment can use the wide dummy areas 502, 504 as an area for forming the power supply mesh. This reduces impedance of the power supply and can improve power integrity. Moreover, the power supply mesh having such wide area will have a very large parasitic capacitance, which contributes to stability of the source voltage.

The dummy areas 502, 504 may have formed therein MOS capacitors connected to the power supply mesh. This further enhances the stability of the source voltage.

The power supply interconnects and the ground interconnects that constitute the power supply mesh have high thermal conductivity. Therefore, the heat generated in the main circuit 508 diffuses outwards through the power supply mesh. The power supply mesh, therefore, not only stabilizes the source voltage, but also provides a cooling mechanism.

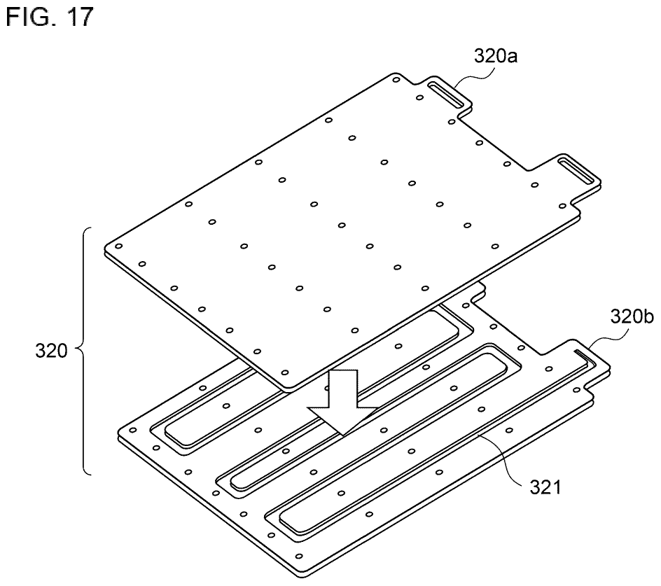

FIG. 17 is an exploded perspective view of the cold plate 320. The cold plate 320 is constituted by bonding two plates, each having a meandering groove 321 formed therein. The grooves 321 serve as a flow channel for a refrigerant.

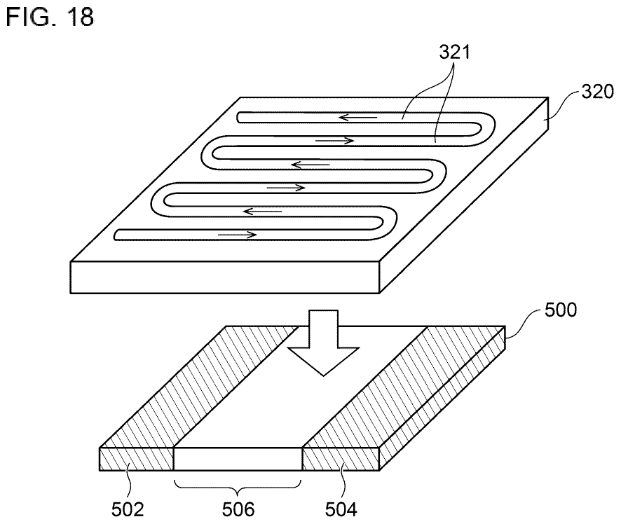

FIG. 18 is a perspective view for explaining cooling of the semiconductor chip 500 with use of the cold plate 320. The cold plate 320 and the semiconductor chip 500 are bonded, while aligning a cooling channel 321 of the cold plate 320 in the first direction of the semiconductor chip 500. That is, the refrigerant in the cooling channel 321 flows across the functional area 506, in a direction from the dummy area 502 towards the dummy area 504, or in the opposite direction. This successfully dissipates the heat generated in the functional area 506 towards the dummy areas 502, 504.

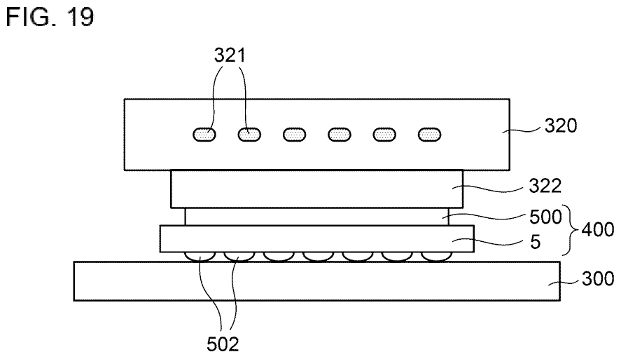

FIG. 19 is a cross-sectional view illustrating a package layout of the pin electronics IC 400.

The pin electronics IC 400 has a flip-chip pin grid array (FC-PGA) package. The pin electronics IC 400 has a semiconductor chip 500 and an interposer 510, wherein the semiconductor chip 500 is flip-chip mounted on the top face of the interposer 510. A ball grid 512 is formed on the back face of the interposer 510. A pin electronics IC 400 is mounted on the printed circuit board 310.

The semiconductor chip 500 of the pin electronics IC 400 is a bare chip that remains exposed without being resin-encapsulated (molded) and is thermally coupled through a thermal interface material (TIM) 322 to the cold plate 320.

It is to be understood by those skilled in the art that the aforementioned embodiments are merely illustrative, and that combinations of the individual constituents or processes may be modified in various ways. Such modified examples will be explained below.

### Modified Example 1

Although having described use of the interposer as a connection interface between the FPC cable 222 and the pin electronics PCB 310, or as a connection interface between the FPC cable 222 and the socket board 210, the present disclosure is not limited thereto.

### Modified Example 2

Although having described, in the embodiment, the interface device 200 with the socket board 210 laid in parallel to the ground, the present disclosure is not limited thereto. For example, the socket board 210 may alternatively be perpendicular to the ground. In this case, the Y-direction typically in FIGS. 5 and 6 will lie in the direction of gravity.

### Modified Example 3

Although having described, in the embodiment, the pin electronics IC 400 as an example of the semiconductor integrated circuit having the structure illustrated in FIG. 15, the present disclosure does not limit types of the semiconductor integrated circuit, and is also applicable to application specific integrated circuit (ASIC), field programmable gate array (FPGA), central processing unit (CPU), graphics processing unit (GPU), micro-processing unit (MPU), dynamic random access memory (DRAM), static random access memory (SRAM), and the like.

Having described the embodiments according to the present disclosure with use of specific terms, the description is merely illustrative for better understanding, and by no means limits the disclosure or the claims. The scope of the present disclosure is defined by the claims, and therefore encompasses any embodiment, Example, and Modified Example having not been described above.

What is claimed is:

1. A semiconductor integrated circuit comprising:
a semiconductor chip;
two dummy areas located on both sides of the semiconductor chip in a first direction, and having no transistor that serves as a heat source arranged therein; and
a main circuit of the semiconductor integrated circuit, formed in an area interposed between the two dummy areas.

2. The semiconductor integrated circuit according to claim 1, wherein the semiconductor chip has a rectangular shape with a long side aligned in the first direction.

3. The semiconductor integrated circuit according to claim 1, wherein each of the two dummy areas has a power supply mesh formed therein.

4. The semiconductor integrated circuit according to claim 3, wherein the power supply mesh has a MOS capacitor connected thereto.

5. The semiconductor integrated circuit according to claim 1, wherein each of the two dummy areas has a length of 3 mm or longer in the first direction.

6. The semiconductor integrated circuit according to claim 1, wherein a length of each of the two dummy areas has a length in the first direction longer than ⅕ of a length of the main circuit in the first direction.

7. A module comprising:
the semiconductor integrated circuit according to claim 1; and
a cold plate having therein a cooling channel, and being thermally coupled to the semiconductor integrated circuit,
and,
the cooling channel of the cold plate being laid in parallel to the first direction.

8. The module according to claim 7, wherein the cooling channel of the cold plate has a U-shaped part that extends towards the first direction and then turns back in an opposite direction.

9. The module according to claim 7, wherein the semiconductor chip of the semiconductor integrated circuit is not encapsulated, and the semiconductor chip is in contact with the cold plate while placing a heat conductive material in between.

10. The module according to claim 7, wherein the semiconductor integrated circuit is a flip chip-pin grid array (FC-PGA) package and is mounted on a printed circuit board while placing an interposer in between.
